(19) United States
(12) Patent Application Publication
(10) Pub. No.: US 2026/0011648 A1
(43) Pub. Date: Jan. 8, 2026

(54) PACKAGES WITH GLASS COMPONENTS AND METHODS OF FORMING THE SAME

(71) Applicant: Taiwan Semiconductor Manufacturing Co., Ltd., Hsinchu (TW)

(72) Inventors: Po-Ching Wu, Hsinchu (TW); Chao-Wei Chiu, Hsinchu (TW); Hsuan-Ting Kuo, Taichung City (TW); Meng-Tsan Lee, Hsinchu (TW); An-Jhih Su, Taoyuan City (TW); Hsiu-Jen Lin, Zhubei City (TW)

(21) Appl. No.: 18/934,458

(22) Filed: Nov. 1, 2024

Related U.S. Application Data
(60) Provisional application No. 63/667,168, filed on Jul. 3, 2024.

(51) Int. Cl. H01L 23/538; H01L 21/48; H01L 23/15; H01L 25/00; H01L 25/065

(52) U.S. Cl. CPC H01L 23/5385; H01L 21/4846; H01L 21/486; H01L 23/15; H01L 23/5384; H01L 25/0652

(57) ABSTRACT

A method includes forming a package substrate comprising forming through-openings in a glass substrate, filling the through-openings to form through-vias in the glass substrate, forming a first interconnect structure underlying the glass substrate, and forming a second interconnect structure overlying the glass substrate. The method further includes forming an interposer over the package substrate, and bonding package components over and electrically connected to the package substrate through the interposer.

### PRIORITY CLAIM AND CROSS-REFERENCE

This application claims the benefit of the following provisionally filed U.S. Patent application: Application No. 63/667,168, filed on Jul. 3, 2024, and entitled “SUBSTRATE STRUCTURE FOR LARGE-SCALE CHIPLET AND PACKAGE INTEGRATION,” which application is hereby incorporated herein by reference.

### BACKGROUND

Interconnect dies have been used for electrically interconnecting device dies and packages. Currently, the interconnect dies are embedded in Chip-on-wafer-on-substrate packages. The wafers in the package are often interposers.

With the increasingly demanding requirement of computing power, the interposers are being made increasingly larger. This posts problems because the overlay window is narrower when the interposers are larger. The problems such as cold joint are more likely to occur.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-13 illustrate the cross-sectional views of intermediate stages in the formation of a package including glass substrates in accordance with some embodiments.

FIG. 14 illustrates a top view of the bridge dies and openings in a glass substrate in accordance with some embodiments.

FIG. 15 illustrates a cross-sectional view of a package including glass substrates in accordance with alternative embodiments.

FIGS. 16-26 illustrate the cross-sectional views of intermediate stages in the formation of a package including interconnect dies in glass substrates in accordance with some embodiments.

FIG. 27 illustrates the cross-sectional view of a package including an organic substrate in accordance with alternative embodiments.

FIG. 28 illustrates the property of a glass in accordance with some embodiments.

FIG. 29 illustrates the composition and atom distribution of an example glass in accordance with some embodiments.

FIG. 30 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a glass substrate(s), which may include package components such as a local silicon interconnect (LSI) die(s) (also referred to as bridge dies) embedded therein and the methods of forming the same are provided. In accordance with some embodiments of the present disclosure, a glass substrate is formed and provided, and through-vias are formed in the glass substrate to form a package substrate or an interposer. A through-opening may be formed in the glass substrate, and a package component such as an LSI die may be placed in the through-opening. Adopting glass substrates, due to the large selection of glass materials with suitable properties such as a wide range of CTEs, enables the selection of forming package components with suitable Coefficient of Thermal Expansion (CTE), so that the warpage of the resulting packages may be reduced.

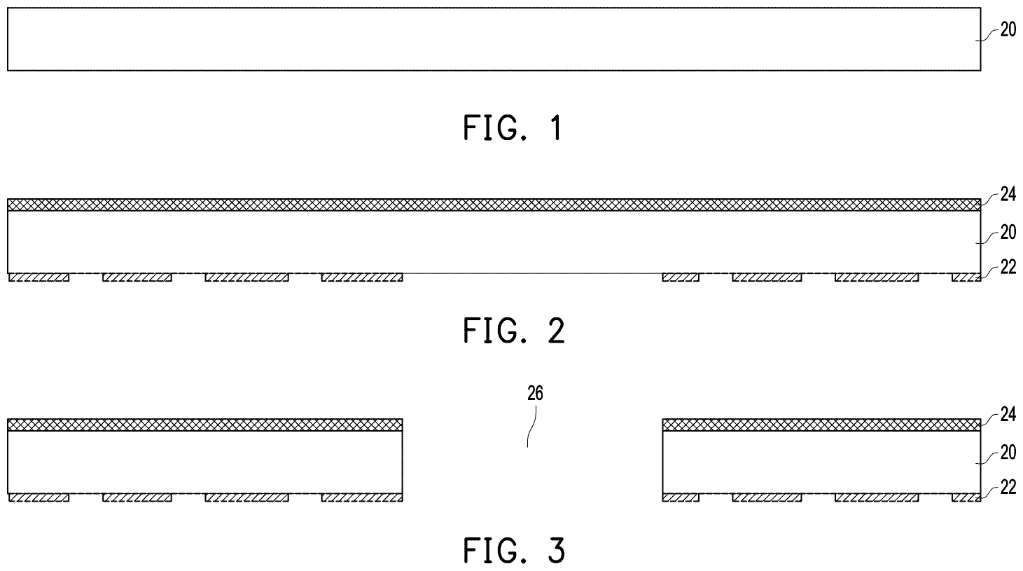

FIGS. 1 through 13 illustrate the cross-sectional views of intermediate stages in the formation of a package in accordance with some embodiments of the present disclosure. The corresponding processes are also reflected schematically in the process flow shown in FIG. 30.

Referring to FIG. 1, glass substrate 20 is provided. Glass substrate 20 may comprise a homogeneous glass, which may comprise SiO₂, B₂O₃, P₂O₅, GeO₂, Li₂O, Na₂O, K₂O, MgO, CaO, SrO, BaO, Al₂O₃, ZrO₂, TiO₂, PbO, ZnO, or the like, or combinations thereof. There may be other materials or elements such as SO₃, SnO₂, Cl, Na, K, Sr, Ti, Al, Si, P, Bi, Te, or the like, or combinations thereof, added into the above listed material. There may also be additives comprising Nd, V, Cr, Mn, Fe, Co, Ni, Cu, Ag, Au, Sn, S, F, Cl, Sn, or the like, or combinations mixed in the aforementioned materials and additives. In accordance with some embodiments, the thickness of glass substrate 20 may be in the range between about 100 μm and about 300 μm.

In accordance with some embodiments, glass substrate 20 may be formed by processes including melting a plurality of materials, refining the molten materials, forming the molten materials into shape by cooling, annealing, cutting, and the like. It is appreciated that while a glass may include some materials such as SiO₂ and Al₂O₃ used in the integrated circuit formation processes, these materials are not necessarily glasses. For example, SiO₂ and Al₂O₃ formed using deposition processes such as Chemical Vapor Deposition (CVD), Atomic Layer Deposition (PVD) processes, and the like, are not glasses. Whether a material is a glass or not is related to the formation process, the main material and other materials and additives therein, and the resulting structure.

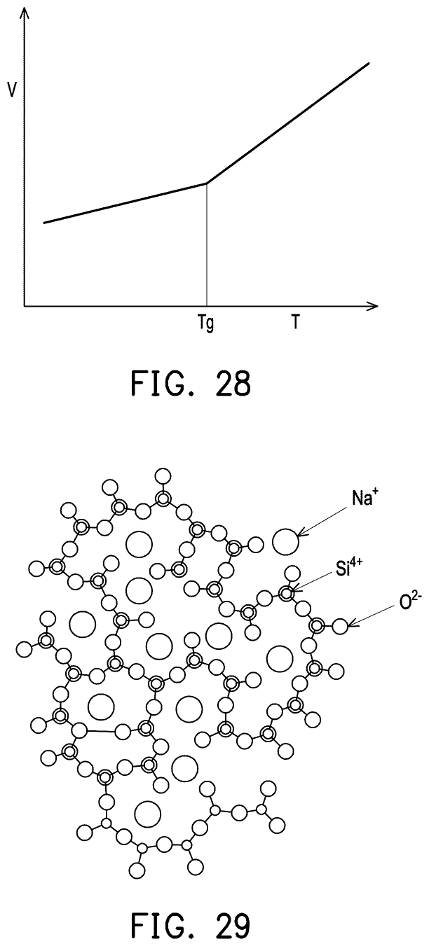

A glass has a glass transition temperature Tg, above which it starts to become rubbery, and the viscosity is gradually reduced with the increase in the temperature. The corresponding behavior is schematically illustrated in FIG. 28, wherein the volume (V) is shown as a function of temperature. It is shown that at glass transition Tg, the glass becomes rubbery and gradually transitions with the increase in the temperature.

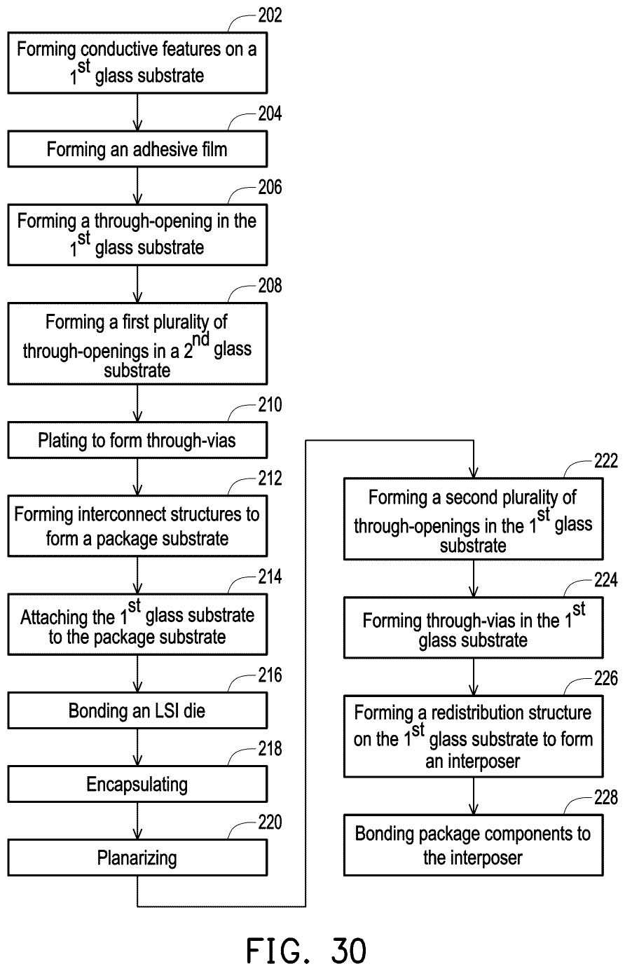

Glasses may have different glass transition temperatures. For example, borosilicate glass, depending on its composition, may have a glass transition temperature in the range between about 440° C. and about 560° C. Soda-Lime Glass glass, depending on its composition, may have a glass transition temperature in the range between about 530° C. and about 570° C. Aluminosilicate glass, depending on its composition, may have a glass transition temperature in the range between about 620° C. and about 790° C. The glasses have amorphous structures. For example, FIG. 29 illustrates the composition and atom distribution of an example soda glass in accordance with some embodiments.

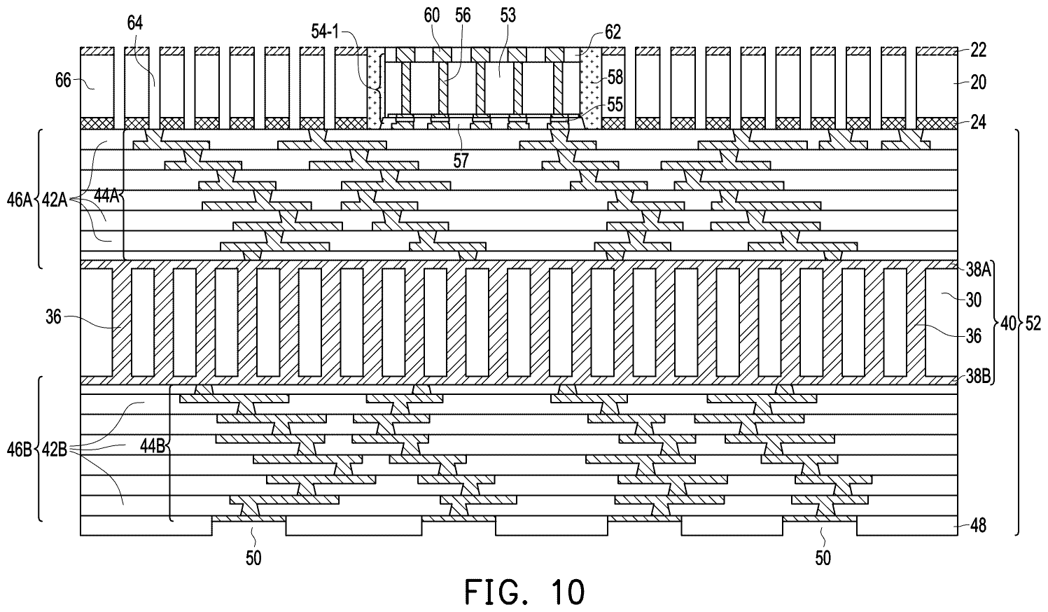

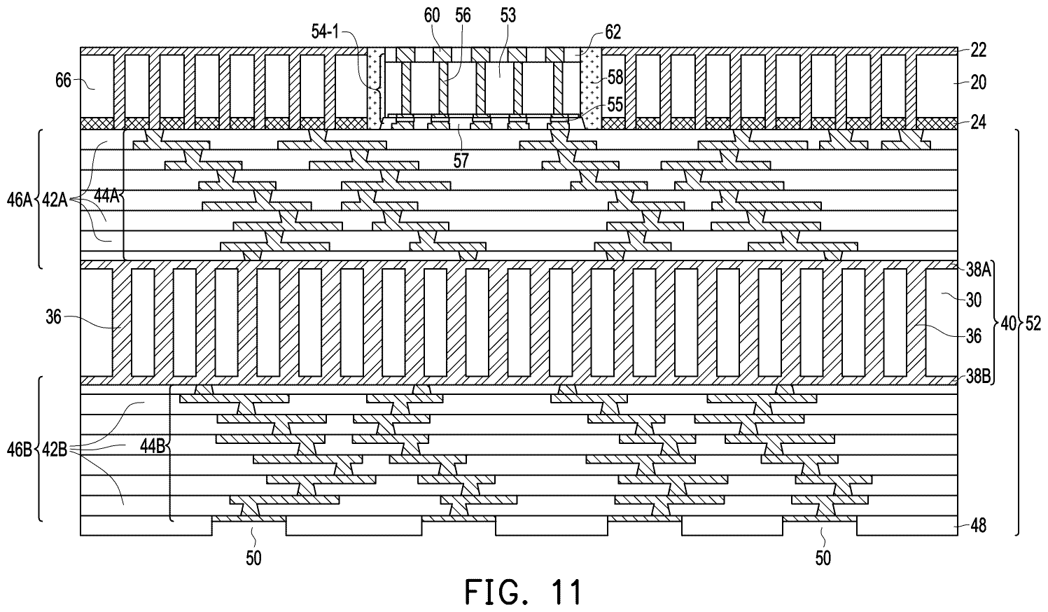

Referring to FIG. 2, conductive features 22, which may include metal lines and/or metal pads, are formed on one side of glass substrate 20. The respective process is illustrated as process 202 in the process flow 200 as shown in FIG. 30. In accordance with alternative embodiments, instead of forming conductive features at this stage, conductive features 22 are formed in the processes shown in FIGS. 10 and 11. Accordingly, conductive features 22 are illustrated as being dashed to indicate that conductive features 22 may be formed in this process, or may be formed in subsequent processes. Conductive features 22 may be formed through a deposition process, which may include a plating process, and a patterning process through etching.

Adhesive film 24 may also be adhered to glass substrate 20 in accordance with some embodiments. The respective process is illustrated as process 204 in the process flow 200 as shown in FIG. 30. Adhesive film 24 may be a blanket layer covering the entire glass substrate 20 in accordance with some embodiments.

Next, as shown in FIG. 3, through-openings 26 may be formed, for example, through laser drilling, blade sawing, etching, or the like. The respective process is illustrated as process 206 in the process flow 200 as shown in FIG. 30. Through-openings 26 penetrate through glass substrate 20 and adhesive film 24. The top-view shapes of through-openings 26 may include rectangular shapes. While one through-opening 26 is illustrated, there may be a plurality of through-openings 26 formed in glass substrate 20 and adhesive film 24. Depending on the package components to be placed in through-openings 26, the through-openings 26 may have shapes and/or sizes same as each other or different from each other.

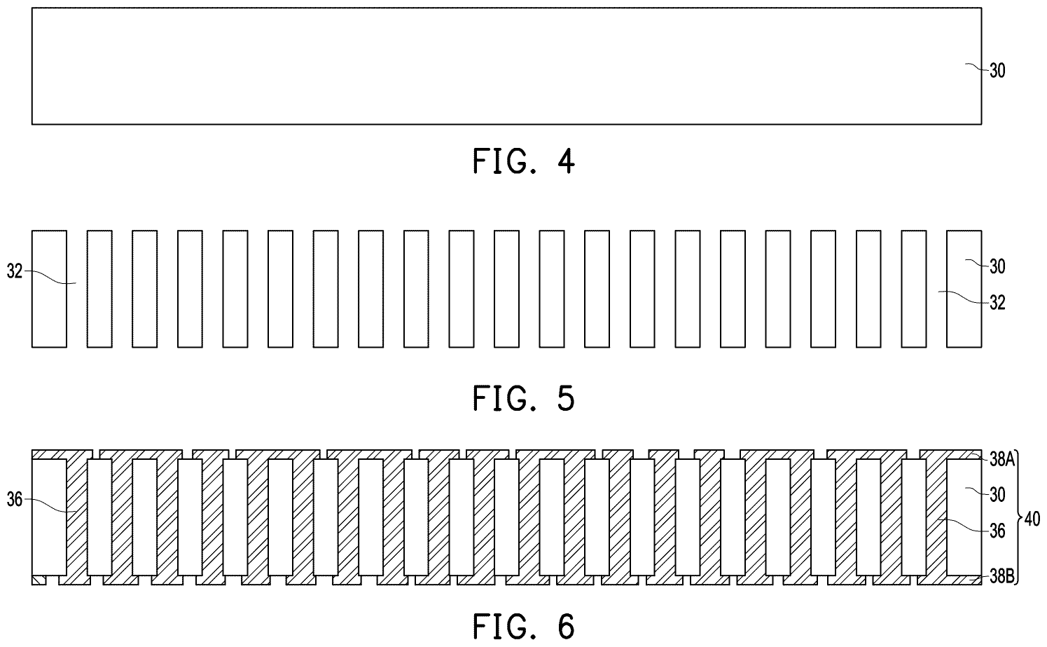

FIGS. 4 through 7 illustrate the formation of package substrate 52 in accordance with some embodiments, which package substrate 52 is formed based on a glass substrate 30. Referring to FIG. 4, glass substrate 30 is formed and provided. The material of glass substrate 30 may be selected from the same group of candidate materials for forming glass substrate 20. The material of glass substrate 30 may also be the same as or different from the material of glass substrate 20. The thickness of glass substrate 30 may be in the range between about 100 μm and about 300 μm.

Referring to FIG. 5, through-openings 32 may be formed, for example, through laser drilling, etching, or the like. The respective process is illustrated as process 208 in the process flow 200 as shown in FIG. 30. Through-openings 32 penetrate through glass substrate 30. The top-view shapes of through-openings 32 may include circles, rectangles, hexagons, octagons, or the like. Through-openings 32 may have sizes same as or different from each other.

Next, referring to FIG. 6, through-openings 32 are filled with a conductive material through a plating process, forming through-vias 36 therein. The respective process is illustrated as process 210 in the process flow 200 as shown in FIG. 30. Through-vias 36 may be formed of a metallic material such as copper, tungsten, aluminum, titanium, nickel, or alloys thereof. In accordance with some embodiments, the lateral dimensions (widths and/or diameters) of through-vias 36 may be in the range between about 5 μm and about 150 μm. the spacings between neighboring through-vias 36 may be in the range between about 50 μm and about 100 μm.

Conductive features 38A and 38B may also be formed on the top side and the bottom side of glass substrate 30, and may or may not be formed in the same plating process for forming through-vias 36. The respective process is also illustrated as process 212 in the process flow 200 as shown in FIG. 30. In accordance with some embodiments, the formation of conductive features 38A and 38B may include plating conductive films on opposing sides of glass substrate 30, which plating process may be (or may not be) performed in the same process as forming through-vias 36, and planarizing the conductive films. The conductive films are then patterned through etching processes to form conductive features 38A and 38B, which may include metal pads and metal lines (also referred to as redistribution lines (RDLs)).

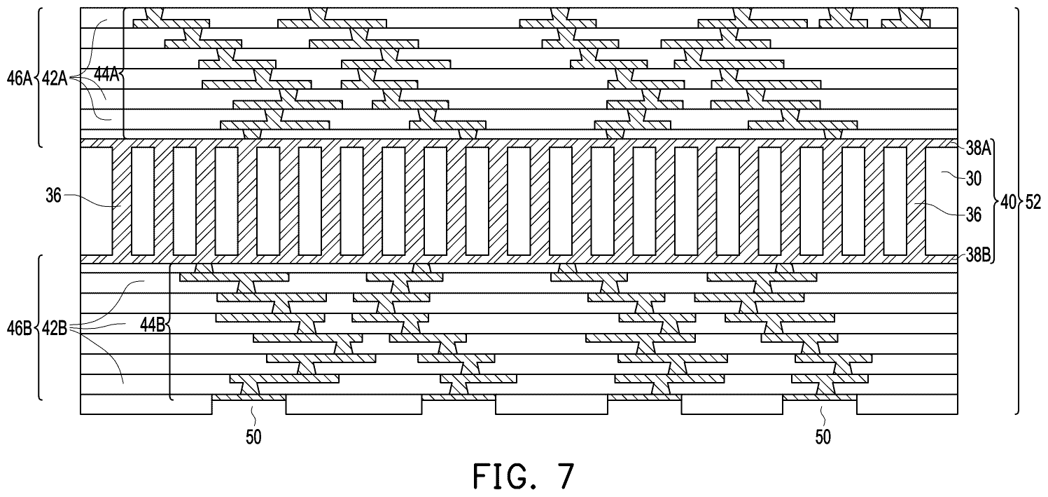

FIG. 7 illustrates the formation of interconnect structures 46A and 46B on the opposite sides of glass substrate 30 to form a package substrate. The respective process is also illustrated as process 212 in the process flow 200 as shown in FIG. 30. Conductive features 38A and 38B, which may include RDLs and metal pads separated from each other, as shown in FIG. 6, are schematically illustrated in FIG. 7, wherein the separation of neighboring RDLs and metal pads is not shown in detail, and the details may be found referring to FIG. 6.

The interconnect structure 46A may include dielectric layers 42A and redistribution lines (RDLs) 44A in dielectric layers 42A. The interconnect structure 46B may include dielectric layers 42B and RDLs 44B in dielectric layers 42B. The interconnect structures 46A and 46B are also referred to as build-up layers. The formation of dielectric layer 42A and 42B and RDLs 44A and 44B may include forming and patterning dielectric layers, and plating the RDLs from the openings in the dielectric layers.

Dielectric layers 42A and 42B may be formed of or comprising Ajinomoto Build-up Film (ABF) films, which are laminated and patterned. Other dielectric materials such as polybenzoxazole (PBO), polyimide, benzocyclobutene (BCB), inorganic dielectric materials (such as SiO₂ and SiN), or the like may also be used. RDLs 44A and 44B may be formed of or comprise aluminum, copper, nickel, titanium, and/or the like. The interconnect structure 46B may have the same number of layers as, and is symmetrical to, the interconnect structure 46A. Accordingly, the stress applied on the glass substrate 30 is reduced.

Further referring to FIG. 7, solder mask 48 is applied and patterned. Solder mask 48 comprises a dielectric material, and is used to isolate and define the regions for the subsequently formed solder regions. Solder mask 48 may have openings 50 therein, which may be used for forming large solder regions (Ball Grid Arrays (BGAs)) therein. The features shown in FIG. 7 are collectively referred to as package substrate 52 hereinafter.

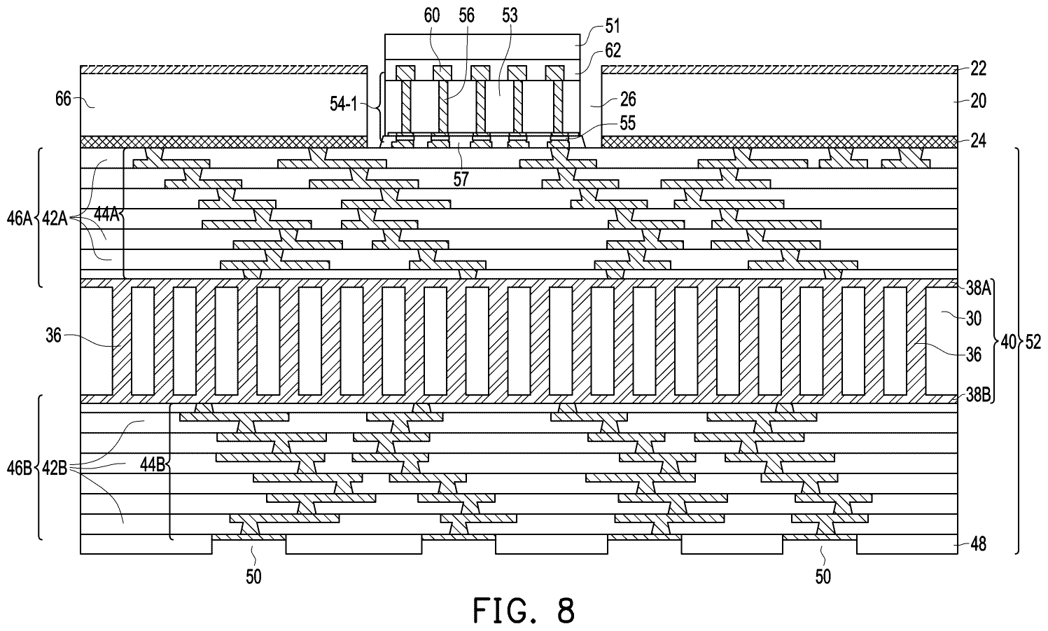

Referring to FIG. 8, the glass substrate 20 as shown in FIG. 3 is adhered to package substrate 52 through the adhesion of adhesive film 24. The respective process is illustrated as process 214 in the process flow 200 as shown in FIG. 30. Conductive features 22, which may include RDLs and metal pads separated from each other, as shown in FIG. 6, may or may not have been formed, and thus are illustrated as being dashed. The conductive features 22, if formed, may include RDLs and metal pads that are formed as a plurality of discrete features separated from each other. The separation of the discrete features is not shown in detail, and may be found referring to FIG. 3.

FIG. 8 also illustrates the bonding of LSI die 54-1 (also referred to as a bridge die) in accordance with some embodiments, for example, through solder regions 55. The respective process is illustrated as process 216 in the process flow 200 as shown in FIG. 30. LSI die 54-1 may include a semiconductor substrate 53 such as a silicon substrate. Through-vias 56 penetrate through the silicon substrate 53, and are used for connecting the features over LSI die 54-1 to the RDLs 44A. Underfill 57 may be dispensed between LSI die 54-1 and package substrate 52. In accordance with some embodiments, a supporting substrate 51 is attached to the LSI die 54-1, with dielectric layer 62 (such as a PBO layer) being located between supporting substrate 51 and LSI die 54-1. Dielectric layer 62 embeds electrical connectors 60 (such as metal pillars) therein.

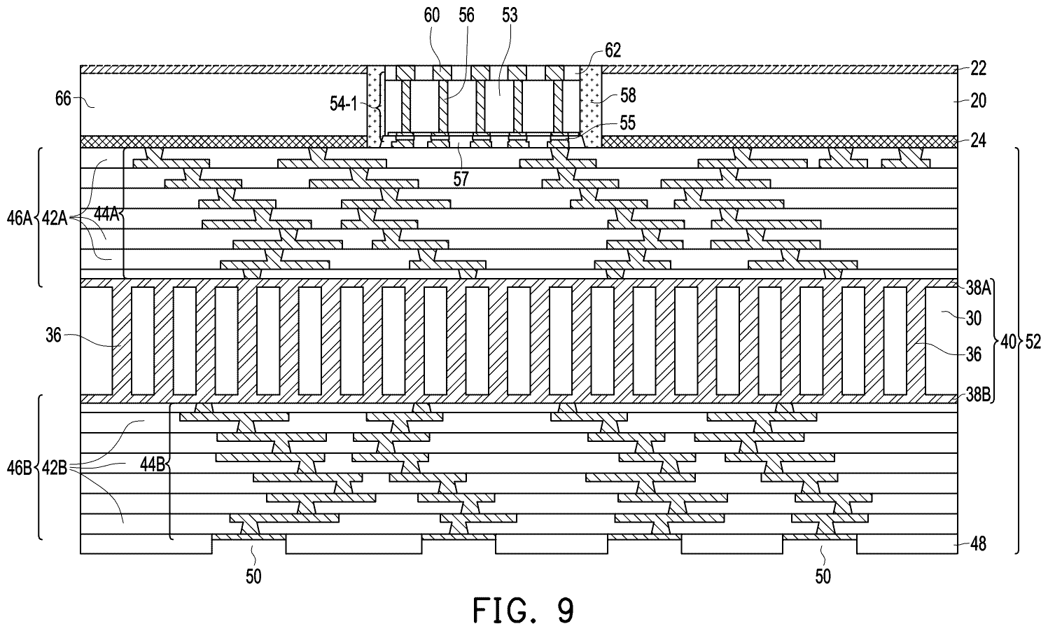

Next, as shown in FIG. 9, encapsulant 58 is dispensed into through-opening 26 and to encapsulate LSI die 54-1 therein. The respective process is illustrated as process 218 in the process flow 200 as shown in FIG. 30. Encapsulant 58 may include a molding compound, a molding underfill, an epoxy, a resin, and/or other materials. When the encapsulation is finished, the top surface of encapsulant 58 is higher than the top ends of supporting substrate 51 (FIG. 8).

Encapsulant 58 may include a base material, which may be a polymer, a resin, an epoxy, or the like, and filler particles in the base material. The filler particles may be dielectric particles formed of silica, alumina, boron nitride, or the like, and may have spherical shapes. In accordance with alternative embodiments, encapsulant 58 may include inorganic dielectric materials, such as a silicon nitride layer and a silicon oxide layer over the silicon nitride layer.

Next, a planarization process is performed, so that the portions of encapsulant 58 over glass substrate 20 (and conductive features 22, if already formed) are removed. The respective process is illustrated as process 220 in the process flow 200 as shown in FIG. 30. The planarization process may include a Chemical Mechanical Polish (CMP) process or a mechanical grinding process. The conductive features 22, if already formed, are revealed in accordance with some embodiments. In accordance with alternative embodiments in which conductive features 22 have not been formed, glass substrate 20 will be revealed.

In addition, in accordance with some embodiments in which the supporting substrate 51 (FIG. 8) is attached to LSI die 54-1, the supporting substrate 51 is also removed through polishing in the planarization process, revealing dielectric layer 62 and electrical connectors 60 of the LSI die 54-1.

FIG. 10 illustrates the formation of through-openings 64 in accordance with some embodiments. The respective process is illustrated as process 222 in the process flow 200 as shown in FIG. 30. Through-openings 64 may be formed through laser drilling, drilling using drilling bits, etching, or the like. In accordance with some embodiments in which conductive features 22 are pre-formed as shown in FIG. 3, through-openings 64 may be formed aside of and next to (but do not penetrate through) the conductive features, or may be formed penetrating through conductive features 22.

Openings 64 penetrate through glass substrate 20 and adhesive film 24. The formation process may be performed using the top conductive features in the top layer of RDLs 44A as stop layers. Although not illustrated, each of the through-openings 64 may be stopped by one of the underlying RDLs 44A, which may be conductive pads or vias that are wider than the respective overlying openings 64 in accordance with some embodiments.

Next, a conformal metal seed layer (not shown) may be deposited, and a plating process such as an electrical chemical plating process is performed to fill through-openings 64. Through-vias 66 are thus formed. The respective process is illustrated as process 224 in the process flow 200 as shown in FIG. 30. The resulting structure is shown in FIG. 11. In addition, more conductive features 22 may be formed. The conductive features 22 formed in this process may be combined with the conductive features 22 formed in the process shown in FIG. 3, if already formed. Otherwise, all of the conductive features 22 are formed in this process. Although conductive features 22 are schematically illustrated, and the separation of neighboring conductive features 22 is not illustrated, the conductive features 22 may include a plurality of conductive pads and RDLs that are electrically connected to through-vias 66, but are physically and electrically separated from each other, similar to what is shown in FIG. 3.

In accordance with some embodiments, the formation of conductive features 22 may include a planarization process to planarize the plated material on top of glass substrate 20 to form a blanket conductive film, and patterning the blanket conductive film to form conductive features 22.

In accordance with alternative embodiments, after the formation of the metal seed layer, a patterned plating mask (such as a patterned photoresist) may be formed, and conductive features 22 are patterned in the openings in the plating mask to have desirable patterns. The plating mask is then removed to reveal the underlying metal seed layer, and the metal seed layer is then etched.

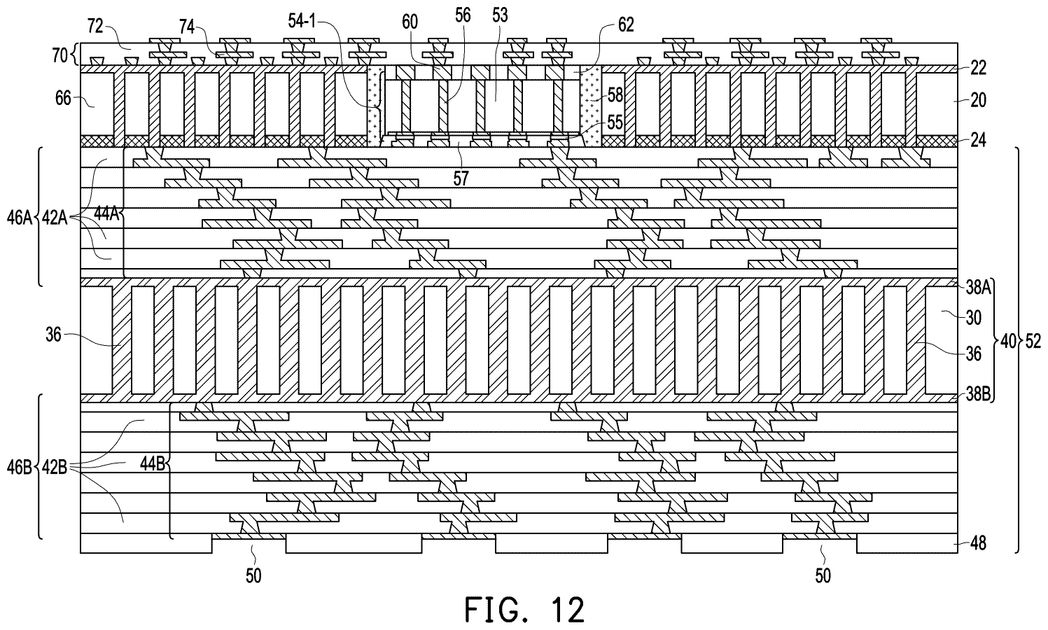

FIG. 12 illustrates the formation of redistribution structure 70 (also referred to as an interconnect structure), which may include dielectric layers 72 and RDLs 74. The respective process is illustrated as process 226 in the process flow 200 as shown in FIG. 30. Dielectric layers 72 may be formed of an organic material such as PBO, polyimide, or the like. Alternatively, dielectric layers 72 may comprise inorganic dielectric materials, and RDLs 74 may be formed therein through damascene processes. Under-Bump Metallurgies (UBMs) and solder regions may also be formed on top of RDLs 74. Interposer 76, which is formed based on glass substrate 20, is thus formed.

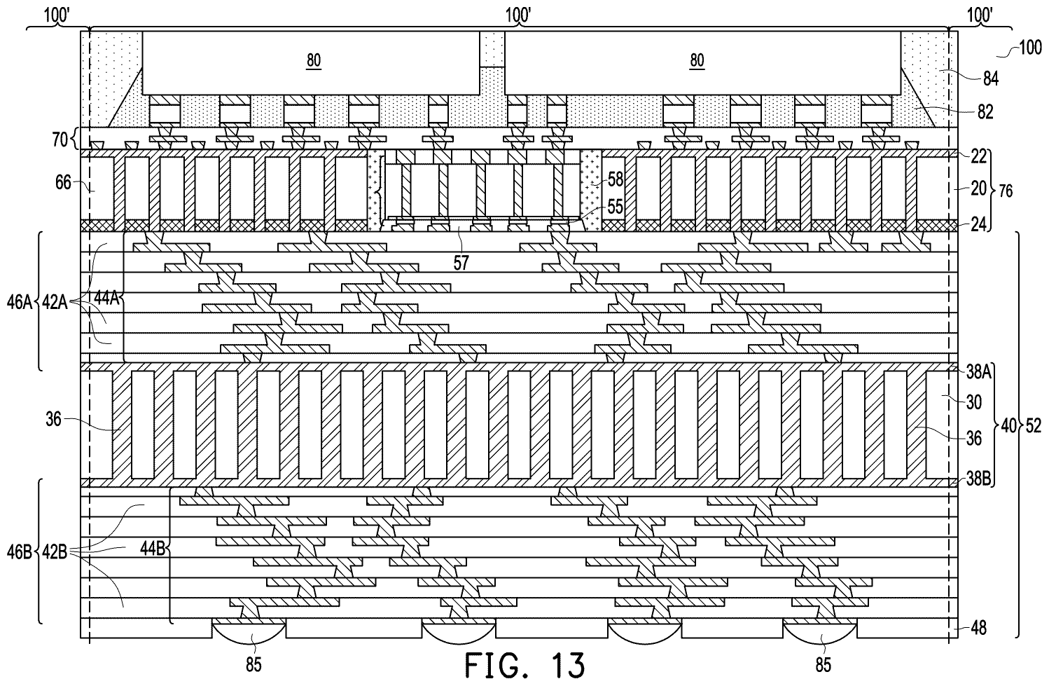

FIG. 13 illustrates the bonding of package components 80 to interposer 76. The respective process is illustrated as process 228 in the process flow 200 as shown in FIG. 30. Package 100 (a reconstructed wafer) is thus formed. Each of package components 80 may include a High-bandwidth memory (HBM) stack, a package including a device die(s) bonded to an interposer, a discrete device die, a System-on-Chip (SoC) die, or the like. Package components 80 may also include device dies such as Deep Trench Capacitors (DTCs), Integrated Voltage Regulators (IVRs), active dies, independent passive devices (IPDs), or the like. Underfill 82 may be dispensed in the gaps between package components 80 and the underlying interposer 76. Encapsulant 84, which may include a molding compound, may be dispensed to encapsulate package components 80 therein. Solder regions 85 may be formed as the bottom features of package substrate 52.

In accordance with some embodiments, a singulation process is performed to saw the structure shown in FIG. 12 into a plurality of packages 100′ that are identical to each other. In accordance with alternative embodiments, the package 100 is a wafer-level package including a single package therein, and the package may be sawed through edge trimming, or may not be sawed or edge-trimmed. The resulting singulated packages 100′ or the unsawed and not edge-trimmed package 100 may then be bonded to other package components such as a printed circuit board through solder regions 85.

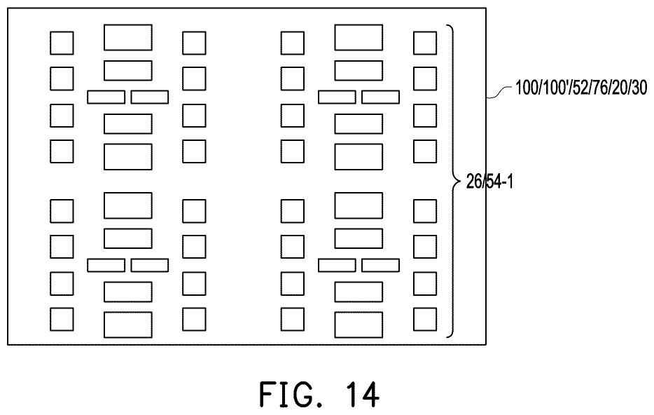

FIG. 14 illustrates a top view of package 100/100′, which may be either package 100′ (after sawed and singulated) or package 100, in accordance with some embodiments. The unsawed package 100 may also include rounded edges, and may be fully circular or may have rounded edges and straight edges. The package 100′/100 may be a large-scale package, for example, with sizes greater than about 100 mm×100 mm, which is formed based on a single glass-based package substrate 52 and a single glass-based interposer 76. Glass substrates 20 and 30 may expand to the edges of package 100′/100. The package 100′/100 may include a plurality of package components 80 (not shown), which are interconnected by a plurality of LSI dies 54-1. The plurality of LSI dies 54-1 are located in a plurality of openings 26. The large-scale package 100′/100 may be used in a performance-demanding application such as an artificial intelligence application.

Adopting glasses to form the package components such as package substrates and interposers have some advantageous features. Due to the large selection of the materials of glasses, the glasses with desirable properties are readily available and may be selected to form package components. For example, the glasses with suitable CTEs may be selected to form glass substrates 20 and 30, so that the overall warpage of package 100′/100 may be reduced. The glasses also have high modulus values and may be made with high degree of flatness. These properties of the glasses allow for the enlarged process window and enable pitch scaling.

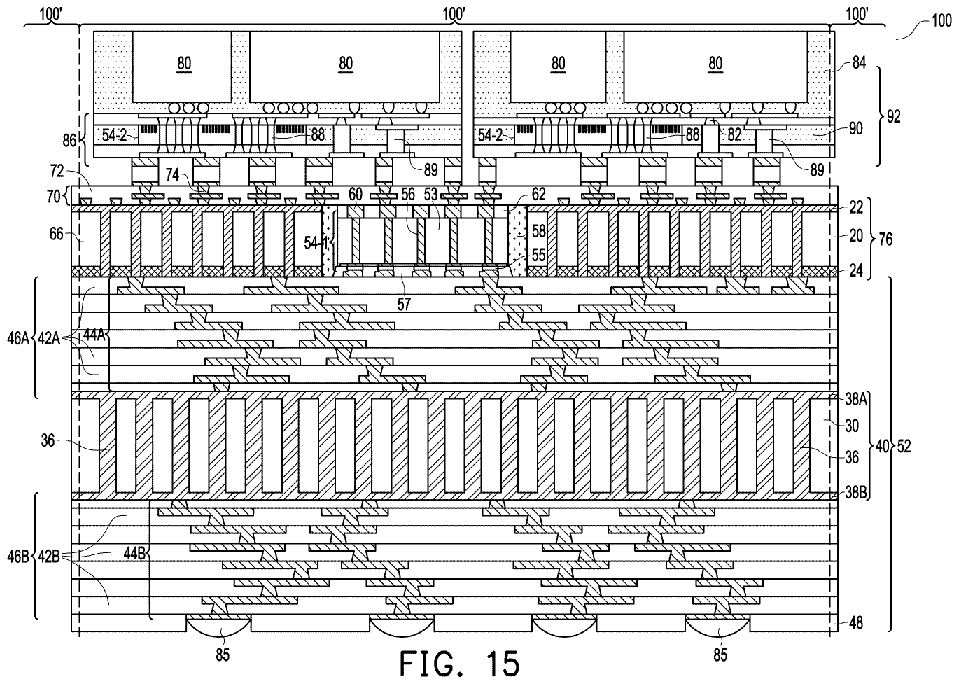

FIG. 15 illustrates the cross-sectional view of a package in accordance with alternative embodiments of the present disclosure. Unless specified otherwise, the materials, the structures, and the formation processes of the components in these embodiments and subsequent embodiments are essentially the same as the like components denoted by like reference numerals in the preceding embodiments. The details regarding the materials, the structures, and the formation processes provided in each of the embodiments throughout the description may be applied to any other embodiment whenever applicable.

The package 100/100′ as shown in FIG. 15 is essentially the same as the package 100/100′ shown in FIGS. 13 and 14, except that additional package components and through-vias are inserted between package components 80 and interposer 76. Each of package components 80 may also include a High-bandwidth memory (HBM) stack, a package including a device die(s) bonded to an interposer, a discrete chip, an SoC die, a power module, a photonic package, or the like.

In accordance with some embodiments, package components 80 are bonded to interposers 86 first to form packages 92. Packages 92 are referred to as chip-on-wafer (CoW) packages, wherein in the bonding, package components 80 are in the form of chips/packages, and interposers 86 are in the form of wafers. The packages 92 are sawed from the respective wafer-level packages, and are bonded to interposer 86. Interposer 86 may include package components 54-2, which may be LSI dies and thus are referred to as LSI dies 54-2, while package components 54-2 may also include other types of package components such as integrated passive devices (such as capacitors, inductors, or the like). Encapsulant 90 encapsulates LSI dies 54-2 therein. Through-vias 88 are formed in encapsulant 90. Through-vias 89 are formed in encapsulants 90.

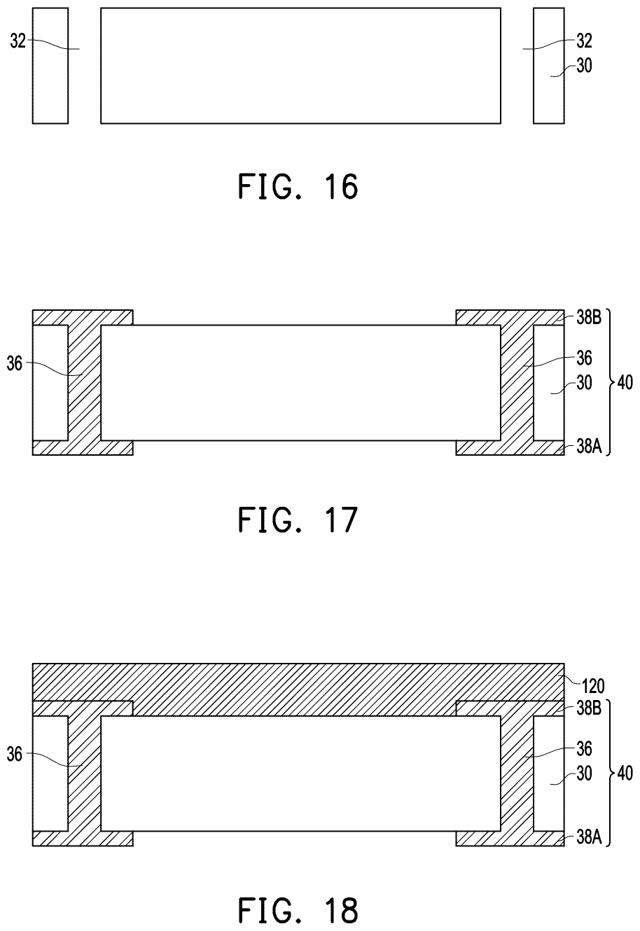

FIGS. 16 through 26 illustrate the formation of package 100′/100 in accordance with alternative embodiments. These embodiments are essentially the same as the embodiments as shown in FIG. 13, except that additional package components such as LSI dies, device dies with TSVs, single-sided device dies, integrated passive devices, or the like, are embedded in glass substrate 30 in addition to the features as shown in FIG. 13.

Referring to FIG. 16, glass substrate 30 is provided as a blanket substrate. The material of glass substrate 30 may be selected from the same group of candidate materials for forming glass substrate 20. The material of glass substrate 30 may also be the same as or different form the material of glass substrate 20. The thickness of glass substrate 30 may be in the range between about 100 μm and about 300 μm.

Further referring to FIG. 16, through-openings 32 may be formed, for example, through laser drilling, etching, or the like. Through-openings 32 penetrate through glass substrate 30. The top-view shapes of through-openings 32 may include circles, rectangles, hexagons, octagons, or the like. Through-openings 32 may have sizes same as or different from each other.

Next, referring to FIG. 17, through-openings 32 are filled with a conductive material through a plating process, forming through-vias 36 therein. Through-vias 36 may be formed of a metallic material such as copper, tungsten, aluminum, titanium, nickel, or alloys thereof. In accordance with some embodiments, the lateral dimensions (widths and/or diameters) of through-vias 36 may be in the range between about 5 μm and about 150 μm. the spacings between neighboring through-vias 36 may be in the range between about 50 μm and about 100 μm.

Conductive features 38A and 38B may also be formed on the front side and the backside of glass substrate 30, and may or may not be formed in the same plating process for forming through-vias 36. In accordance with some embodiments, the formation of conductive features 38A and 38B may include plating conductive films on opposing sides of glass substrate 30, which plating may be performed in the same process as forming through-vias 36, and planarizing the conductive films. The conductive films are then patterned through etching to form conductive features 38A and 38B, which may include metal pads and RDLs. Neighboring conductive features 38A and 38B may be spaced apart from each other (as shown in FIG. 6 for details), with some portions of the surfaces of glass substrate 30 being exposed through the spacings between neighboring conductive features 38A and 38B.

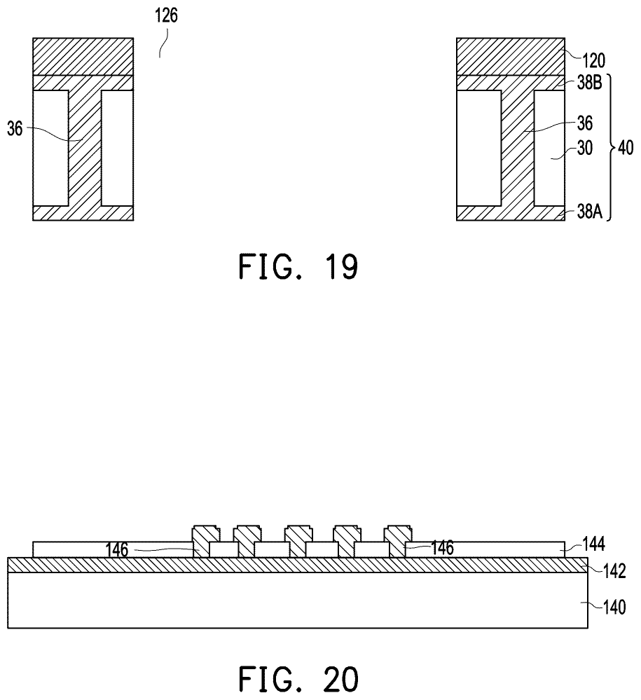

FIG. 18 illustrates the attachment of adhesive film 120 to conductive features 38A and glass substrate 30. Next, as shown in FIG. 19, through-openings 126 may be formed, for example, through laser drilling, blade sawing, etching, or the like. Through-openings 126 penetrate through glass substrate 30 and adhesive film 120. The top-view shapes of through-openings 126 may be rectangular shapes. While one through-opening 126 is illustrated, there may be a plurality of through-openings 126 formed. Depending on the package components to be placed in through-openings 126, the through-openings 126 may have shapes and/or sizes same as each other or different from each other.

FIGS. 20 through 25 illustrate the integration of package components 54-3 with glass substrate 30 in accordance with some embodiments. Referring to FIG. 20, carrier 140 is provided, and release film 142 is formed on carrier 140. Carrier 140 may be a glass carrier, a silicon wafer, an organic carrier, or the like. Release film 142 may be formed of a polymer-based material (such as a Light-To-Heat-Conversion (LTHC) material), which is capable of being decomposed under a heat-carrying radiation such as a laser beam, so that carrier 140 may be de-bonded from the overlying structures that will be formed in subsequent processes.

Dielectric layer 144 and bond pads 146 are formed over carrier 140. Dielectric layer 144 may be formed of a polymer. The polymer may be a photo-sensitive material such as polybenzoxazole (PBO), polyimide, benzocyclobutene (BCB), or the like, which may be patterned using a photo-lithography process including a light-exposure process and a development process. It is appreciated that while one layer of dielectric layer 144 and one layer of bond pads 146 are illustrate, an interconnect structure including a plurality of layers of RDLs and bond pads may be formed.

Bond pads 146 may be formed through plating. The formation of bond pads 146 may include patterning dielectric layer 144, forming a metal seed layer (not shown), forming a patterned mask (not shown) such as a photoresist over the metal seed layer, and then performing a metal plating process on the exposed seed layer. The patterned mask and the portions of the metal seed layer covered by the patterned mask are then removed, leaving bond pads 146. In accordance with some embodiments, the metal seed layer includes a titanium layer and a copper layer over the titanium layer. The metal seed layer may be formed using, for example, Physical Vapor Deposition (PVD) or a like process. The plating may be performed using, for example, an electrochemical plating process or an electro-less plating process. The plated material may comprise copper.

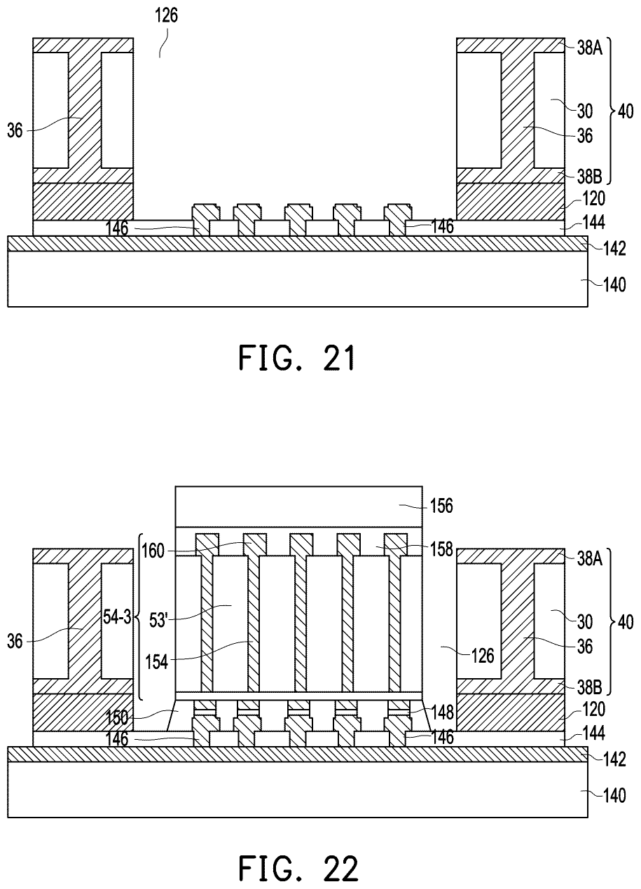

Referring to FIG. 21, glass substrate 30 is attached to dielectric layer 144 through adhesive film 120. Bond pads 146 are exposed through the openings 126. Next, as shown in FIG. 22, package components 54-3 are bonded to bond pads 146, for example, through solder bonding, wherein solder regions 148 are used to bond the electrical connectors of package components 54-3 to bond pads 146. Underfill 150 may also be dispensed into the gaps between package components 54-3 and dielectric layer 144.

LSI die 54-3 may include a semiconductor substrate 53′ such as a silicon substrate. Through-vias 154 penetrate through the silicon substrate 53′, and are used for connecting the features over LSI die 54-3 to the bond pads 146. In accordance with some embodiments, a supporting substrate 156 is attached to the LSI die 54-3, with dielectric layer 158 (such a PBO layer) located between supporting substrate 156 and LSI die 54-3. Dielectric layer 158 embeds electrical connectors 160 (such as metal pillars) therein.

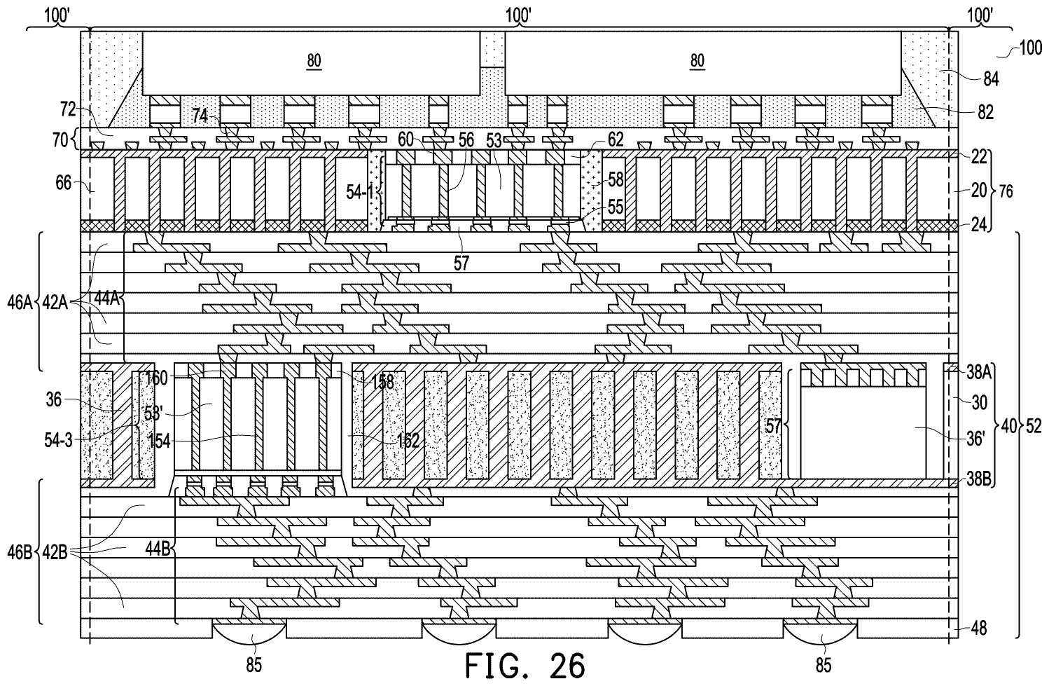

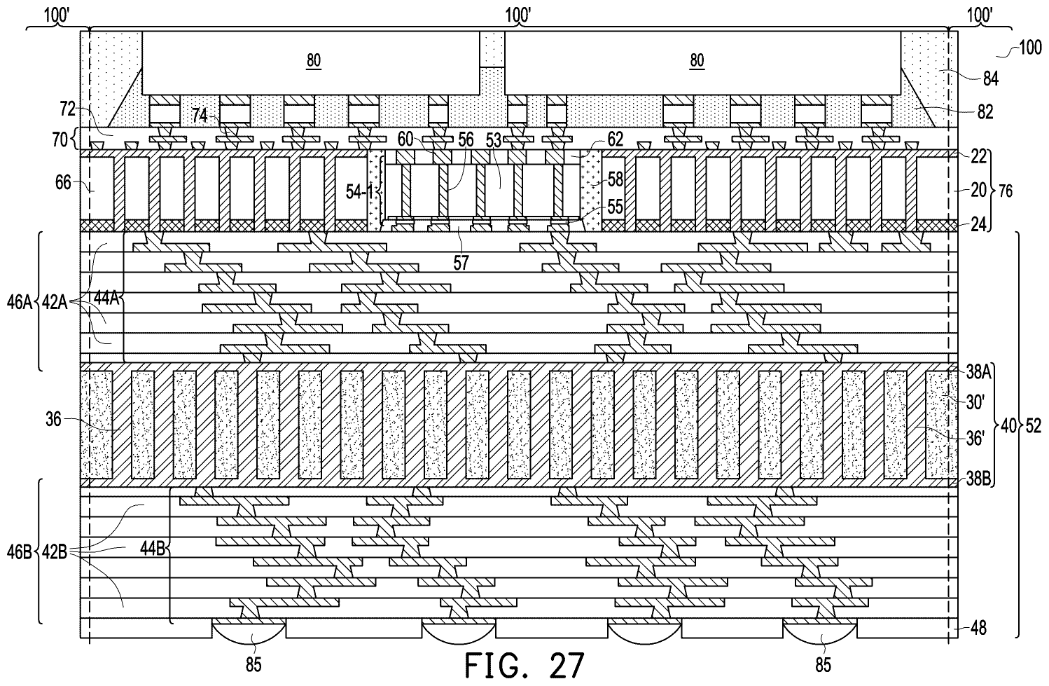

In addition to LSI die 54-3, other types of single-sided package components 57 (refer to FIG. 26) such as active device dies, packages, integrated passive device dies, or the like may also be placed into some of through-openings 126 and bonded to the corresponding bond pads 146. The single-sided package components 57 are free from TSVs therein.

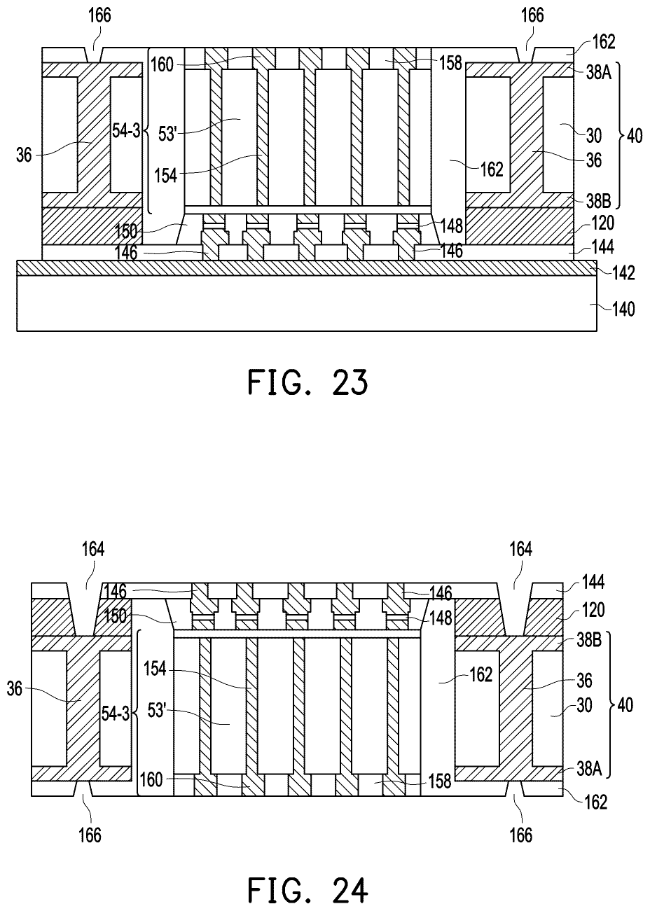

Next, as shown in FIG. 23, encapsulant 162 is dispensed to encapsulate LSI die 54-3 and package components 57 therein. Encapsulant 162 may include a molding compound, a molding underfill, an epoxy, and/or a resin, or other materials. When the encapsulation is finished, the top surface of encapsulant 162 may be higher than the top ends of conductive features 38A and the top surfaces of LSI die 54-3.

Encapsulant 162 may include a base material, which may be a polymer, a resin, an epoxy, or the like. In accordance with some embodiments, the encapsulant 162 is formed of a homogenous material such as a polymer, a resin, or the like, without filler particles therein. In accordance with alternative embodiments, the encapsulant 162 may include filler particles in the base material. The filler particles may be dielectric particles formed of silica, alumina, boron nitride, or the like, and may have spherical shapes. Alternatively, encapsulant 162 may include an inorganic dielectric material(s), for example, a conformal silicon nitride layer and a silicon oxide layer over the silicon nitride layer.

Next, a planarization process is performed, so that some portions of encapsulant 162 over glass substrate 20 (and conductive features 22, if already formed) are removed. The planarization process may include a CMP process or a mechanical grinding process. In addition, in accordance with some embodiments in which the supporting substrate 156 is attached to LSI die 54-3, the supporting substrate 156 is also removed in the planarization process, revealing dielectric layer 158 and electrical connectors 160 of the LSI die 54-3.

In accordance with some embodiments, a layer of encapsulant 162 is left on top of conductive features 38B. Although not illustrated, the neighboring conductive features 38B may be spaced apart from each other, with the gaps in between filled with encapsulant 162, which is physical contact with the exposed portions of glass substrate 30. Openings 166 may be formed in encapsulant 162 to reveal conductive features 38A.

Next, glass substrate 30 and the package components 54-3 bonded therein are de-bonded from carrier 140, for example, by projecting a laser beam onto adhesive film 142, so that adhesive film 142 is decomposed.

FIG. 24 illustrates the glass substrate 30 and the package components 54-3 that have been de-bonded from carrier 140. FIG. 24 illustrates an upside-down view of the structure shown in FIG. 23. In accordance with some embodiments, openings 164 are formed, for example, by laser drilling, drilling using drilling bits, etching, or the like. Openings 164 penetrates through adhesive film 120 and dielectric layer 144. Conductive features 38B are thus exposed. It is appreciated that although openings 164 and 166 are shown in the same figure, they may not exist in a same process. For example, openings 166 may be formed first, and the interconnect structures 46A (FIG. 26) may be formed, and then openings 164 are formed, followed by the formation of interconnect structures 46B (FIG. 26).

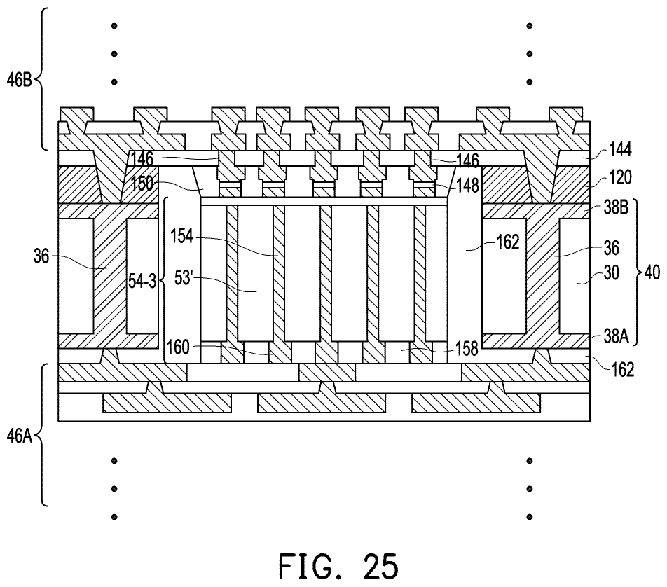

FIG. 25 illustrates the formation of interconnect structures 46A and 46B in accordance with some embodiments. The details of interconnect structures 46A and 46B may be found referring to the discussion of FIG. 7, and are not repeated herein.

In subsequent processes, the remaining portions of package 100 are formed. The details may be found referring to FIGS. 8 through 13, and the details are not repeated herein. The package 100′/100 as shown in FIG. 26 is essentially the same as that in FIG. 13, except the additional package components 54-3 and 57 are formed in glass substrate 30.

FIG. 27 illustrates package 100′/100 in accordance with some embodiments. These embodiments are essentially the same as shown in FIG. 13, except that instead of adopting a glass substrate in package substrate 52, package substrate 52 adopts organic substrate 30′, with Plated Through Holes (PTHs) 36′ formed in the organic substrate 30′.

In accordance with some embodiments, the organic substrate 30′ may be formed of or comprise an organic material such as glass fiber, prepreg (which comprises epoxy, resin, and/or glass fiber), resin coated Copper (RCC), plastic (such as PolyVinylChloride (PVC), Acrylonitrile, Butadiene & Styrene (ABS), Polypropylene (PP), Polyethylene (PE), PolyStyrene (PS), Polymethyl Methacrylate (PMMA), polyimide, molding compound, a molding underfill, an epoxy, resin, or combinations thereof.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By adopting the glass substrates to form package substrates and interposers of large packages, the warpage of the resulting packages may be reduced, and the process window may be increased.

In accordance with some embodiments of the present disclosure, a method comprises forming a package substrate comprising forming first through-openings in a first glass substrate; filling the first through-openings to form first through-vias in the first glass substrate; forming a first interconnect structure underlying the first glass substrate; and forming a second interconnect structure overlying the first glass substrate; forming an interposer over the package substrate; and bonding package components over and electrically connected to the package substrate through the interposer.

In an embodiment, the forming the interposer further comprises forming second through-openings in a second glass substrate; filling the second through-openings to form second through-vias; and forming a third interconnect structure overlying the second glass substrate and electrically coupled to the second through-vias. In an embodiment, the forming the second through-openings comprises laser drilling. In an embodiment, the forming the second through-openings is performed using metallic features in the second interconnect structure as stop layers.

In an embodiment, the forming the interposer further comprises adhering the second glass substrate to the package substrate through an adhesive film, wherein the second through-openings further extend into the adhesive film, and the second through-vias further comprise some portions in the adhesive film.

In an embodiment, the method further comprises bonding a device die to the second interconnect structure, wherein the device die is in an additional opening in the interposer; and forming a third interconnect structure over and electrically connected to the second interconnect structure and the device die. In an embodiment, the device die comprises a local interconnect die, and wherein the third interconnect structure is electrically connected to the second interconnect structure through additional through-vias in the local interconnect die.

In an embodiment, the method further comprises embedding a plurality of local interconnect dies in the interposer. In an embodiment, the method further comprises forming an additional opening in the first glass substrate; and encapsulating an additional device die in the additional opening, wherein the first interconnect structure is further electrically connected to the second interconnect structure through the additional device die. In an embodiment, the package components comprise a package comprising a local interconnect die; and a device die over and electrically coupled to the interposer through the local interconnect die.

In accordance with some embodiments of the present disclosure, a structure comprises a package substrate comprising a lower interconnect structure comprising a first plurality of redistribution lines; a first glass substrate over the lower interconnect structure; a first plurality of through-vias in the first glass substrate; and an upper interconnect structure comprising a second plurality of redistribution lines, wherein the second plurality of redistribution lines are electrically connected to the first plurality of redistribution lines through the first plurality of through-vias; an interposer over the package substrate; package components over and electrically connected to the package substrate through the interposer; and a device die over and electrically coupled to the package substrate.

In an embodiment, the first plurality of through-vias comprise straight edges extending from a top surface to a bottom surface of the first glass substrate. In an embodiment, the interposer comprises a second glass substrate over the upper interconnect structure; a second plurality of through-vias in the second glass substrate; and an additional interconnect structure over the second glass substrate. In an embodiment, the structure further comprises an adhesive film adhering the second glass substrate to the package substrate.

In an embodiment, the second plurality of through-vias comprise some portions in the adhesive film. In an embodiment, one of the second plurality of through-vias comprises a straight edge, and the straight edge comprises a first portion in the second glass substrate, and a second portion in the adhesive film. In an embodiment, the structure further comprises a local interconnect die in the first glass substrate. In an embodiment, the first glass substrate comprises first opposing edges, and the interposer comprises second opposing edges vertically aligned to respective ones of the first opposing edges.

In accordance with some embodiments of the present disclosure, a structure comprises a first package component; a second package component over and electrically coupled to the first package component, wherein a first one of the first package component and the second package component comprises a first glass substrate; a first plurality of through-vias in the first glass substrate; and a first interconnect structure comprising a first plurality of redistribution lines over the first glass substrate and electrically coupled to the first plurality of through-vias; and a local interconnect die in the first glass substrate.

In an embodiment, the first glass substrate is in the first package component, and the second package component further comprises a second glass substrate; a second plurality of through-vias in the second glass substrate, wherein the second plurality of through-vias are electrically connected to the first plurality of through-vias; and a second interconnect structure comprising a second plurality of redistribution lines over the second glass substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a package substrate comprising:
forming first through-openings in a first glass substrate;
filling the first through-openings to form first through-vias in the first glass substrate;
forming a first interconnect structure underlying the first glass substrate; and
forming a second interconnect structure overlying the first glass substrate;
forming an interposer over the package substrate; and
bonding package components over and electrically connected to the package substrate through the interposer.

2. The method of claim 1, wherein the forming the interposer further comprises:
forming second through-openings in a second glass substrate;
filling the second through-openings to form second through-vias; and
forming a third interconnect structure overlying the second glass substrate and electrically coupled to the second through-vias.

3. The method of claim 2, wherein the forming the second through-openings comprises laser drilling.

4. The method of claim 2, wherein the forming the second through-openings is performed using metallic features in the second interconnect structure as stop layers.

5. The method of claim 2, wherein the forming the interposer further comprises:
adhering the second glass substrate to the package substrate through an adhesive film, wherein the second through-openings further extend into the adhesive film, and the second through-vias further comprise some portions in the adhesive film.

6. The method of claim 1 further comprising:
bonding a device die to the second interconnect structure, wherein the device die is in an additional opening in the interposer; and
forming a third interconnect structure over and electrically connected to the second interconnect structure and the device die.

7. The method of claim 6, wherein the device die comprises a local interconnect die, and wherein the third interconnect structure is electrically connected to the second interconnect structure through additional through-vias in the local interconnect die.

8. The method of claim 7 further comprising embedding a plurality of local interconnect dies in the interposer.

9. The method of claim 1 further comprising:
forming an additional opening in the first glass substrate; and
encapsulating an additional device die in the additional opening, wherein the first interconnect structure is further electrically connected to the second interconnect structure through the additional device die.

10. The method of claim 1, wherein the package components comprise a package comprising:
a local interconnect die; and
a device die over and electrically coupled to the interposer through the local interconnect die.

11. A structure comprising:
a package substrate comprising:
a lower interconnect structure comprising a first plurality of redistribution lines;
a first glass substrate over the lower interconnect structure;
a first plurality of through-vias in the first glass substrate; and
an upper interconnect structure comprising a second plurality of redistribution lines, wherein the second plurality of redistribution lines are electrically connected to the first plurality of redistribution lines through the first plurality of through-vias;
an interposer over the package substrate;
package components over and electrically connected to the package substrate through the interposer; and
a device die over and electrically coupled to the package substrate.

12. The structure of claim 11, wherein the first plurality of through-vias comprise straight edges extending from a top surface to a bottom surface of the first glass substrate.

13. The structure of claim 11, wherein the interposer comprises:
a second glass substrate over the upper interconnect structure;
a second plurality of through-vias in the second glass substrate; and
an additional interconnect structure over the second glass substrate.

14. The structure of claim 13 further comprising an adhesive film adhering the second glass substrate to the package substrate.

15. The structure of claim 14, wherein the second plurality of through-vias comprise some portions in the adhesive film.

16. The structure of claim 14, wherein one of the second plurality of through-vias comprises a straight edge, and the straight edge comprises a first portion in the second glass substrate, and a second portion in the adhesive film.

17. The structure of claim 11 further comprising a local interconnect die in the first glass substrate.

18. The structure of claim 11, wherein the first glass substrate comprises first opposing edges, and the interposer comprises second opposing edges vertically aligned to respective ones of the first opposing edges.

19. A structure comprising:
a first package component;
a second package component over and electrically coupled to the first package component, wherein a first one of the first package component and the second package component comprises:
a first glass substrate;
a first plurality of through-vias in the first glass substrate; and
a first interconnect structure comprising a first plurality of redistribution lines over the first glass substrate and electrically coupled to the first plurality of through-vias; and
a local interconnect die in the first glass substrate.

20. The structure of claim 19, wherein the first glass substrate is in the first package component, and the second package component further comprises:
a second glass substrate;
a second plurality of through-vias in the second glass substrate, wherein the second plurality of through-vias are electrically connected to the first plurality of through-vias; and
a second interconnect structure comprising a second plurality of redistribution lines over the second glass substrate.
